(19) United States
(12) Patent Application Publication
(10) Pub. No.: US 2015/0348840 A1
(43) Pub. Date: Dec. 3, 2015

(54) METHODS OF FILLING HIGH ASPECT RATIO FEATURES WITH FLUORINE FREE TUNGSTEN

(71) Applicant: Lam Research Corporation, Fremont, CA (US)

(72) Inventors: Hanna Bamnolker, Cupertino, CA (US); Raashina Humayun, Los Altos, CA (US); Michal Danek, Cupertino, CA (US); Joshua Collins, Sunnyvale, CA (US)

(21) Appl. No.: 14/723,353

(22) Filed: May 27, 2015

Related U.S. Application Data
(60) Provisional application No. 62/006,117, filed on May 31, 2014.
(60) Provisional application No. 62/075,092, filed on Nov. 4, 2014.

(51) Int. Cl. H01L 21/768; C23C 16/52; H01L 21/67; H01L 23/532; H01L 21/285; H01L 21/3213

(52) U.S. Cl. CPC H01L 21/76879; H01L 21/28556; H01L 21/28568; H01L 21/32135; H01L 21/67069; H01L 21/76892; H01L 23/53257; C23C 16/52

(57) ABSTRACT

Provided herein are methods and apparatus for depositing and etching tungsten. The methods involve using tungsten chlorides (WClₓ) as both precursor and etchant. In some embodiments, the exposing the substrate to a WClₓ precursor and a reducing agent at a first set of conditions to deposit a first tungsten layer in a feature on a substrate; and exposing the substrate to a WClₓ precursor and a reducing agent at a second set of conditions to etch the first tungsten layer. According to various embodiments, transitioning from a deposition to etch regime can involve one or more of increasing a WClₓ flux, decreasing a temperature, and changing the WClₓ precursor. Also provided are related apparatus.

### CROSS-REFERENCE TO RELATED APPLICATIONS

This application claims benefit under 35 U.S.C. §119(e) of U.S. Provisional Patent Application No. 62/006,117, filed May 31, 2014, and titled “METHODS OF FILLING HIGH ASPECT RATIO FEATURES WITH FLUORINE FREE TUNGSTEN,” and also claims benefit under 35 U.S.C. §119(e) of U.S. Provisional Patent Application No. 62/075,092, filed Nov. 4, 2014, and titled “METHODS OF FILLING HIGH ASPECT RATIO FEATURES WITH FLUORINE FREE TUNGSTEN,” both of which are herein incorporated by reference in their entireties and for all purposes.

### BACKGROUND

Tungsten film deposition using chemical vapor deposition (CVD) techniques is an integral part of semiconductor fabrication processes. For example, tungsten films may be used as low resistivity electrical connections in the form of horizontal interconnects, vias between adjacent metal layers, and contacts between a first metal layer and the devices on a silicon substrate. In an example tungsten deposition process, a barrier layer is deposited on a dielectric substrate, followed by deposition of a thin nucleation layer of tungsten film. Thereafter, the remainder of the tungsten film is deposited on the nucleation layer as a bulk layer. Conventionally, the tungsten bulk layer is formed by the reduction of tungsten hexafluoride (WF₆) with hydrogen (H₂) in a chemical vapor deposition process.

### SUMMARY

One aspect of the subject matter described herein is a method of depositing tungsten on a substrate. The method includes exposing the substrate to a tungsten chloride and a reducing agent at a first set of conditions to deposit a first tungsten layer in a feature on a substrate by chemical vapor deposition (CVD) and exposing the substrate to a tungsten chloride and a reducing agent at a second set of conditions to etch the first tungsten layer.

According to various embodiments, the tungsten chloride compound used in the deposition and etching operations may be the same or different. Tungsten chlorides (WClₓ) include WCl₂, WCl₄, WCl₅, WCl₆, and mixtures thereof. Examples of reducing agents include hydrogen (H₂).

In some embodiments, etching the first tungsten layer includes a non-conformal etch such that the reduction in the average thickness of the first tungsten layer near an opening of the feature is greater than the reduction in the average thickness of first tungsten layer inside the feature. In some embodiments, transitioning from the first set of conditions to the second set of conditions comprises lowering a temperature. In some embodiments, transitioning from the first set of conditions to the second set of conditions includes increasing a WClₓ flux. In some embodiments, transitioning from the first set of conditions to the second set of conditions includes lowering a chamber pressure. In some embodiments, transitioning from the first set of conditions to the second set of conditions includes increasing a WClₓ flowrate. In some embodiments, transitioning from the first set of conditions to the second of conditions includes increasing a WClₓ concentration.

Another aspect of the subject matter relates to a method including exposing a feature partially filled with tungsten to WClₓ to thereby remove a portion of the tungsten in the partially filled feature. In some embodiments, the feature may be exposed to hydrogen (H₂) as well. In some embodiments, the reduction in the average thickness of the tungsten near an opening of the feature is greater than the reduction in the average thickness of tungsten inside the feature.

Another aspect of the subject matter disclosed herein relates to an apparatus for processing substrates. The apparatus may include (a) one or more process chambers comprising a pedestal configured to hold a substrate; (b) at least one outlet; (c) one or more process gas inlets coupled to one or more process gas sources; and (d) a controller for controlling operations in the apparatus, including machine-readable instructions for: (i) introducing a tungsten chloride and a reducing agent to one of the one or more process chambers; and (ii) after (i), introducing a tungsten chloride and a reducing agent to one of the one or more process chambers, wherein transitioning from (i) and (ii) comprises instructions for switching from an deposition regime to an etching regime.

In some embodiments, wherein the controller includes instructions for transitioning from (i) to (ii) by increasing a tungsten chloride concentration. In some embodiments, wherein the controller includes instructions for transitioning from (i) to (ii) by decreasing a temperature of the substrate. In some embodiments, the controller includes instructions for transitioning from (i) to (ii) by changing the tungsten chloride. In some embodiments, the controller includes instructions for transitioning from (i) to (ii) by increasing a tungsten chloride flowrate.

These and other aspects are described further below with reference to the Figures.

### BRIEF DESCRIPTION OF DRAWINGS

FIG. 1 illustrates an example of a semiconductor substrate containing a high aspect ratio feature during different stages of semiconductor processing in accordance with certain embodiments.

FIG. 2 is a process flow diagram depicting operations performed in accordance with the described embodiments.

FIG. 3A illustrates schematic representations of one example of feature cross-sections at different stages of a filling process.

FIG. 3B shows an example of bottom-up fill of a feature according to certain embodiments.

FIG. 4 is a schematic of an example of a processing system suitable for conducting tungsten thin film deposition and etch processes in accordance with certain embodiments.

FIG. 5 is a schematic of an example of deposition station in accordance with certain embodiments.

FIG. 6 is a pressure curve showing tungsten (W) and titanium nitride (TiN) thickness as a function of pressure for WCl₆/H₂ exposure at 450° C. and 550° C.

FIG. 7 is a graph showing CVD deposition rate and etch transition as a function of precursor concentration for WCl₅ and WCl₆.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor device fabrication often involves the deposition of tungsten films, particularly in trenches or vias to form interconnects. In a conventional methods of depositing tungsten films, a nucleation tungsten layer is first deposited into a via or contact. In general, a nucleation layer is a thin conformal layer that serves to facilitate the subsequent formation of a bulk material thereon. The tungsten nucleation layer may be deposited to conformally coat the sidewalls and bottom of the feature. Conforming to the underlying feature bottom and sidewalls can be critical to support high quality deposition. Nucleation layers are often deposited using atomic layer deposition (ALD) or pulsed nucleation layer (PNL) methods.

In a PNL technique, pulses of reactant are sequentially injected and purged from the reaction chamber, typically by a pulse of a purge gas between reactants. A first reactant can be adsorbed onto the substrate, available to react with the next reactant. The process is repeated in a cyclical fashion until the desired thickness is achieved. PNL is similar to ALD techniques. PNL is generally distinguished from ALD by its higher operating pressure range (greater than 1 Torr) and its higher growth rate per cycle (greater than 1 monolayer film growth per cycle). Chamber pressure during PNL deposition may range from about 1 Torr to about 400 Torr. In the context of the description provided herein, PNL broadly embodies any cyclical process of sequentially adding reactants for reaction on a semiconductor substrate. Thus, the concept embodies techniques conventionally referred to as ALD.

After the tungsten nucleation layer is deposited, bulk tungsten is typically deposited by a non-sequential chemical vapor deposition (CVD) process by reducing tungsten hexafluoride (WF₆) using a reducing agent such as hydrogen (H₂). In the context of the disclosed embodiments, non-sequential CVD embodies processes in which reactants are together introduced to a reactor for a vapor-phase reaction. PNL and ALD processes are distinct from CVD processes and vice versa.

Conventional deposition of tungsten has involved the use of the fluorine-containing tungsten precursor WF₆. However, the use of WF₆ results in some incorporation of fluorine into the deposited tungsten film. As devices shrink, features become smaller and the detrimental effects electromigration as well as ion diffusion become more prominent, thereby causing device failure. The presence of fluorine can cause electromigration and/or fluorine diffusion into adjacent components and damages contacts, thereby reducing the performance of the device. Tungsten films containing traces of fluorine can thereby pose integration and reliability issues, as well as device performance issues related to the underlying films or device structures, such as vias and gates.

Fluorine-free tungsten (FFW) precursors are useful to prevent such reliability and integration or device performance issues. Current FFW precursors include metal organic precursors, but undesirable traces of elements from the metal organic precursors may be incorporated in the tungsten film as well, such as carbon, hydrogen, nitrogen, and oxygen. Some metal organic fluorine-free precursors are also not easily implemented or integrated in tungsten deposition processes.

Methods disclosed herein involve filling features with fluorine-free tungsten (FFW). In some embodiments, excellent step coverage of tungsten films using a fluorine-free tungsten chloride (WClₓ) precursor is provided. The processes can achieve FFW film as well as fill of high aspect ratio trenches, by first perform a partial deposition, etch, and then complete the fill with second deposition. In some embodiments, this can be achieved in-situ in a single chamber, by only changing the process conditions from deposition conditions to etching conditions using WClₓ as both deposition precursor and etchant. In some embodiments, multiple deposition-etch cycles may be performed to fill a feature.

Filling features with tungsten-containing materials may cause formation of seams inside the filled features. A seam can form when a layer that is being deposited on the side walls of the feature thickens to the point that it seals off by forming a pinch point; any void space below this point is isolated from the environment of the processing chamber. This pinching prevents precursors and/or other reactants from entering remaining void spaces, and they remain unfilled. A void space may be an elongated seam extending throughout a portion of the filled feature along the feature's depth direction. This void space or seam is also sometimes referred to as a keyhole because of its shape.

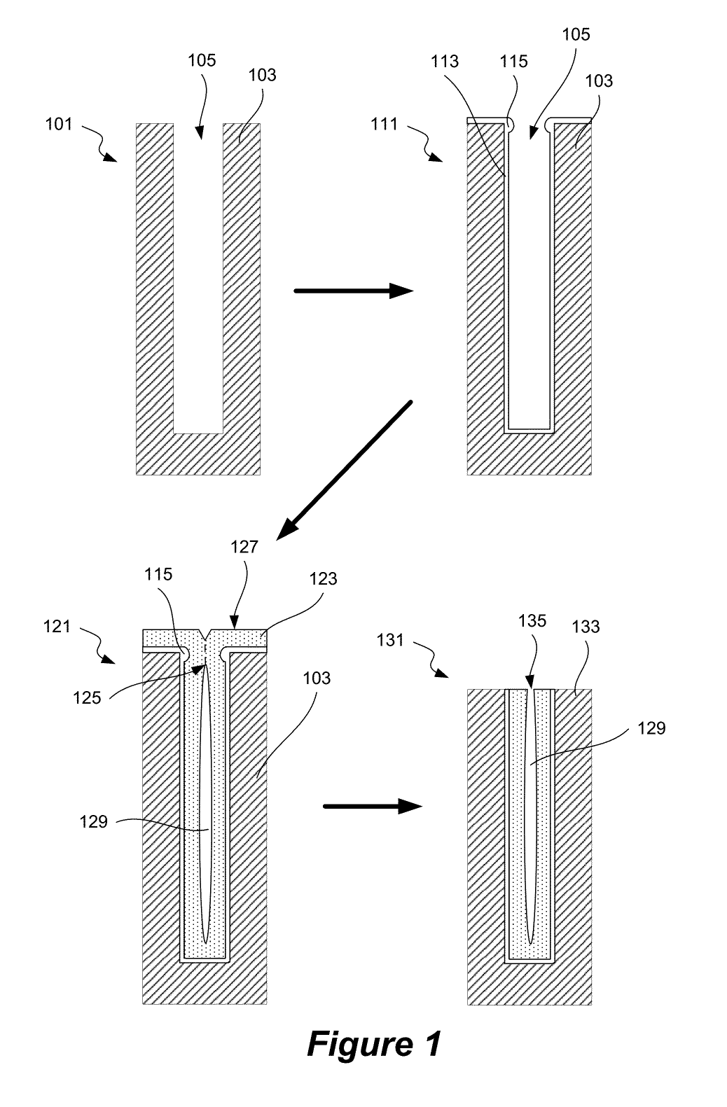

There are multiple potential causes for seam formation. One is an overhang formed near the feature opening during deposition of tungsten-containing materials or, more typically, other materials, such as a diffusion barrier layer or a nucleation layer. FIG. 1 illustrates an example of a semiconductor substrate containing a high aspect ratio feature during different stages of semiconductor processing in accordance with certain embodiments. The first cross-section 101 shows a substrate 103 with a pre-formed feature hole 105. The substrate may be a silicon wafer, e.g., a 200-mm wafer, 300-mm wafer, or 450-mm wafer. The feature hole 105 may have an aspect ratio of at least about 2:1 or, in more specific embodiments, of at least about 4:1. As discussed further below, the methods disclosed herein may be used to fill features having much higher aspect ratios, for example, at least 12:1, or at least 30:1. The feature hole 105 may also have a cross-section dimension near the opening (e.g., opening diameter, line width, etc.) of between about 10 nanometers to 500 nanometers, for example, between about 25 nanometers to 300 nanometers. The feature hole is sometimes referred to as an unfilled feature or simply a feature.

In the next stage (cross-section 111), the substrate 103 is shown with a deposited an under-layer 113 lining the feature hole 105, which may be a diffusion barrier layer, an adhesion layer, a nucleation layer, a combination of thereof, or any other applicable material. Because many deposition processes do not have good step coverage properties, more material is deposited on the field region and near the opening than inside the feature and the under-layer 113 may form an overhang 115. With the overhang 115 a part of the under-layer 113, the under-layer 113 may be thicker near the opening than inside the feature. For the purposes of this description, “near the opening” is defined as an approximate position or an area within the feature (i.e., along the side wall of the feature) corresponding to between about 0-10% of the feature depth measured from the field region. In certain embodiments, the area near the opening corresponds to the area at the opening. Further, “inside the feature” is defined as an approximate position or an area within the feature corresponding to between about 20-60% of the feature depth measured from the field region on the top of the feature. Typically, when values for certain parameters (e.g., thicknesses) are specified “near the opening” or “inside the feature”, these values represent a measurement or an average of multiple measurements taken within these positions/areas. In certain embodiments, an average thickness of the under-layer near the opening is at least about 10% greater than that inside the feature. In more specific embodiments, this difference may be at least about 25%, at least about 50%, or at least about 100%. Distribution of a material within a feature may also be characterized by its step coverage. For the purposes of this description, “step coverage” is defined as a ratio of two thicknesses, i.e., the thickness of the material inside the feature divided by the thickness of the material near the opening. In certain examples, the step coverage of the under-layer is less than about 100% or, more specifically, less than about 75% or even less than about 50%.

The next cross-section 121 illustrates the feature hole filled with the tungsten-containing materials 123. A deposition process may result in a conformal layer of the materials 123 built-up over the under-layer 113. This deposited layer follows the shape of the under-layer 113 including its overhang 115. In certain embodiments and, particularly, in later stages of the deposition process (e.g., right before feature closing), the layer 123 may become less conformal resulting in poor step coverage (i.e., more material being deposited near the opening than inside the feature). As the layer 123 thickens, it may close the feature forming a pinch point 125. Often some additional material is deposited above the pinch point 125 before the deposition process is stopped. Because of the overhang 115 and, in certain embodiments, the poor step coverage of the layer 123, the closed feature may have an unfilled void below the reference point 125. The void is referred to as a seam 129. The size of the seam 129 and the position of the reference point 125 with respect to the field region 127 depend on the size of the overhang 115, as well as the size, aspect ratio, and bowing of the feature, deposition process parameters, and other parameters.

Finally, cross-section 131 shows the substrate 133 after chemical-mechanical planarization (CMP), which removes a top layer from the substrate 103. CMP may be used to remove an overburden from the field region, such as parts of layers 113 and 123 that were present on the top surface of the substrate 103. Typically the substrate 103 is also thinned down during CMP to form the substrate 133. If the pinch point 125 falls above the planarization level of the CMP process, as in FIG. 1, the seam 129 opens up and is exposed to environment through seam opening 135.

Another cause that is not illustrated in FIG. 1 but that nevertheless may lead to seam formation or enlarging seams and moving the reference point closer to the field region is curved (or bowed) side walls of feature holes, which are also referred to as bowed features. In a bowed feature the cross-sectional dimension of the cavity near the opening is smaller than that inside the feature. Effects of these narrower openings in the bowed features are somewhat similar to the overhang problem described above. Further, bowed features may also have under-layers with overhangs and encounter other seam formation causes compounding negative effects of seam formation.

Provided herein are methods of filling features with fluorine-free tungsten (FFW). The methods involve using tungsten chlorides (WClₓ) as both precursor and etchant. The methods can be used to contour and shape tungsten film in the feature to provide a desired step coverage. For example, step coverage greater than 100%, e.g., up to 150% may be provided. In some embodiments, the methods involve depositing tungsten in the feature using WClₓ to partially fill the feature and performing non-conformal etching to removed tungsten from certain locations in the feature. In some embodiments, additional deposition-etch cycles may be performed. After the one or more deposition-etch cycles, feature fill may be completed with tungsten deposition. This methods enable complete fill of challenging contact structures with re-entrant etch profiles or overhanging barrier films. In some embodiments, the fill occurs in a bottom up fill manner. Since WClₓ is used as a precursor, fluorine free W film is achieved, which has excellent reliability characteristics, therefore improved device performance. The methods address the needs of current manufacturing technology nodes (≧2X nm) as well as advanced development nodes (≦2X nm).

Tungsten chlorides include WCl₂, WCl₄, WCl₅ and WCl₆, as well as mixtures of these. Further, while the below description chiefly describes fluorine free methods, in other embodiments, WClₓ may include tungsten fluoro-chlorides WFₓCl_{y} and mixtures of tungsten chlorides WClₓ and tungsten fluorides WF_{y}.

Further, while the description below focuses on tungsten (W) feature fill, aspects of the disclosure may also be implemented in deposition of tungsten-containing materials. It should be understood that the any of the tungsten films described herein may include some amount of other compounds, dopants and/or impurities such as nitrogen, carbon, oxygen, boron, phosphorous, sulfur, silicon, germanium and the like, depending on the particular precursors and processes used. The tungsten content in the film may range from 20% to 100% (atomic) tungsten. In many implementations, the films are tungsten-rich, having at least 50% (atomic) tungsten, or even at least about 60%, 75%, 90%, or 99% (atomic) tungsten. For example, feature fill using one or more techniques described herein may be used to fill features with tungsten-containing materials such as tungsten nitride (WNₓ), tungsten carbide (WCₓ), and tungsten carbonitride (WCₓN_{y}). In some implementations, the films may be a mixture of metallic or elemental tungsten (W) and other tungsten-containing compounds such as tungsten carbide (WC), tungsten nitride (WN), etc. Carbides and nitrides may be formed by introducing carbon-containing and/or nitrogen-containing reactants during deposition or by exposing an already formed tungsten layer to such compounds. Further, the methods described herein may be used for tungsten deposition outside the context of feature fill, for example, to deposit and/or etch blanket layers or overburden layers.

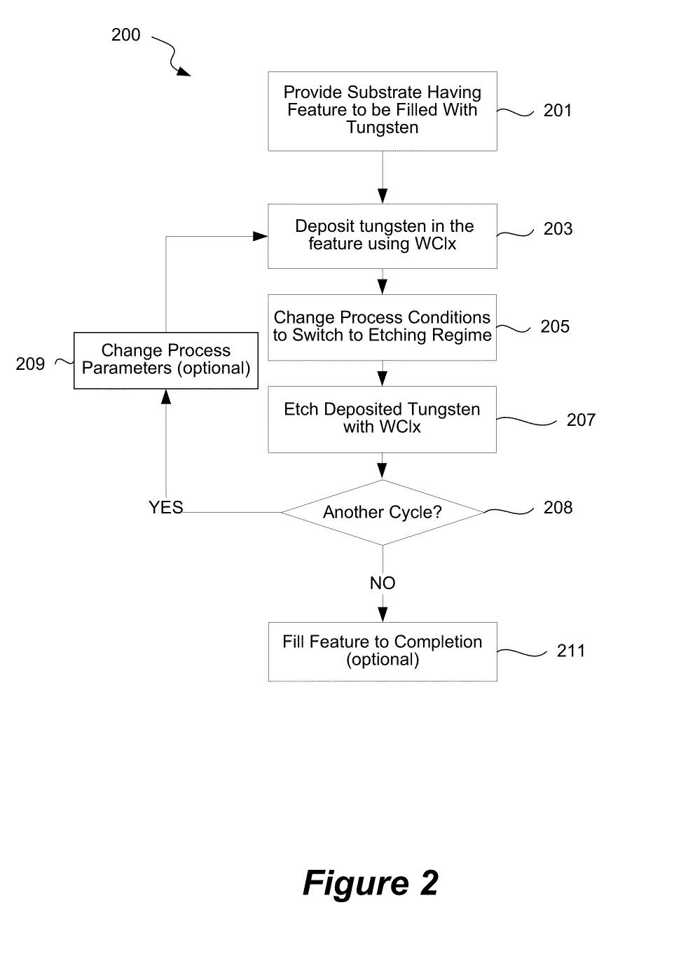

FIG. 2 is a process flow diagram depicting operations performed in accordance with the described embodiments. A method 200 may start with providing a substrate having one or more features to be filled with tungsten (block 201). For example, the substrate may be provided to a deposition station inside a multi-station chamber or to a single-station chamber. The substrate may have an under-layer lining the feature, such as a diffusion barrier layer. Certain substrate and under-layer details are provided above in the context of FIG. 1.

In certain embodiments, the average thickness of the under-layer near the opening is at least about 25% greater than that inside the feature. In a more general sense, the substrate may have an under-layer with an overhang. In some cases, a layer of previously deposited bulk tungsten may be present in the feature. A diffusion barrier layer may be previously deposited onto the substrate to form a conformal layer that prevents diffusion of materials used to fill the features into surrounding materials of the substrate. Materials for the diffusion barrier layer may include tungsten nitride, titanium, titanium nitride, and others. Example barrier layer thicknesses may be between about 10 Angstroms and 500 Angstroms thick, such as between about 25 Angstroms and 200 Angstroms thick.

The method 200 proceeds with deposition of tungsten (W) in the feature using WClₓ (block 203). As indicated above, WClₓ may include any tungsten chloride or a mixture of different tungsten chlorides, e.g., WCl₆, WCl₅, etc. In some embodiments, block 203 may involve exposing the feature to WClₓ and a reducing agent to partially fill the feature. According to various embodiments, block 203 can involve an ALD or PNL-type reaction (in which the reducing agent and WClₓ are introduced sequentially), a CVD reaction or both. For example, a nucleation layer may first be formed with introducing silane (SiH₄) and/or diborane (B₂H₆) and WClₓ sequentially into a deposition chamber one or more times, followed by a CVD reaction in which WClₓ is reduced by H₂. Reducing agents such as silanes and boranes are generally stronger than hydrogen (H₂). As such, silanes, boranes and germanes may be used as a reducing agent for nucleation layer deposition and hydrogen for bulk layer deposition.

Methods of depositing tungsten using WCl₆ as a precursor are described in U.S. patent application Ser. No. 14/703,732, filed May 4, 2015, titled “Methods of Preparing Tungsten and Tungsten Nitride Thin Films Using Tungsten Chloride Precursor,” which is incorporated by reference herein. CVD may also use other reducing agents such as boranes, silanes or germanes. Any tungsten chloride (WClₓ) including WCl₂, WCl₄, WCl₅, WCl₆, and mixtures thereof may be used.

A CVD process implemented in block 203 may be a non-sequential CVD reaction (in which the reducing agent and WClₓ are introduced simultaneously), a pulsed CVD process, or a sequential CVD process. In some embodiments, block 203 may involve two or more of these, for example, a sequential CVD process followed by a non-sequential CVD process.

In some embodiments, block 203 involves a sequential CVD process as described in concurrently-filed U.S. patent application Ser. No. 14/723,270 (Attorney Docket Number LAMRP184/3601-1US), which is incorporated by reference herein for the purpose of describing sequential CVD processes. Sequential CVD processes implement separate exposures to each reactant such that the reactants are not flowed into the chamber at the same time during deposition. Rather, each reactant flow is introduced to a chamber housing the substrate in temporally separated pulses in sequence, repeated one or more times in cycles. Generally a cycle is the minimum set of operations used to perform a surface deposition reaction one time. The result of one cycle is the production of at least a partial film layer on a substrate surface. Because of their cyclic nature, sequential CVD processes are similar to ALD processes. However, in sequential CVD, reactants do not necessarily adsorb onto active sites on the substrate and in some embodiments, the reaction may not be self-limiting. For example, reactants used in sequential CVD may have a low adsorption rate. Moreover, reactants on the surface of the substrate may not necessarily react with a second reactant when the second reactant is introduced. Rather, in some embodiments of sequential CVD, some reactants on the substrate remain unreacted during the cycle, and are not reacted until a subsequent cycle. Some reactants may not react due to stoichiometric properties, steric hindrance, or other effects. In some embodiments, a sequential CVD process involves alternating pulses of WClₓ and H₂.

Sequential CVD processes are distinguished from non-sequential CVD, pulsed CVD, ALD and nucleation layer deposition. Non-sequential CVD processes involve simultaneous exposure of two reactants, such that both reactants are flowed at the same time during deposition. For example, bulk tungsten may be deposited by exposing a substrate to hydrogen and tungsten pentachloride at the same time for a duration sufficient to fill features. H₂ and WCl₅ react during the exposure to deposit tungsten into the features. In pulsed CVD processes, one reactant is continuously flowed while the other reactant is pulsed, but the substrate is exposed to both reactants during deposition to deposit material during each pulse. For example, a substrate may be exposed to a continuous flow of H₂ while WCl₅ is pulsed, and WCl₅ and H₂ react during the pulse to deposit tungsten.

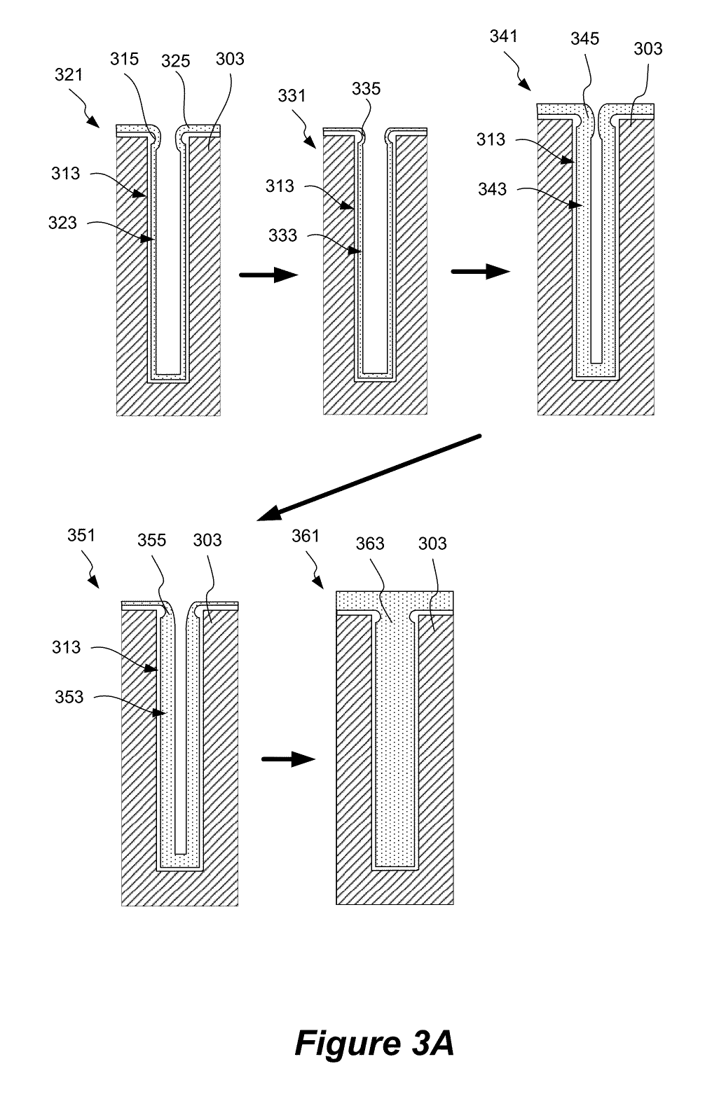

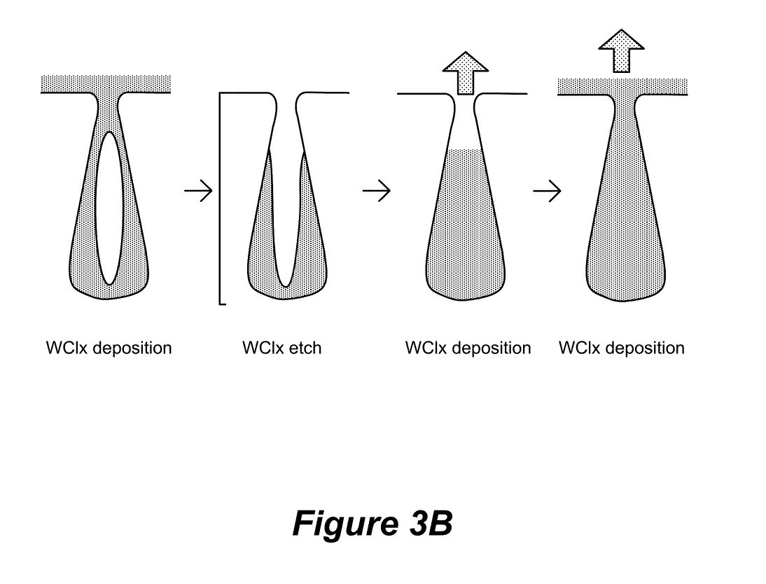

FIG. 3A illustrates schematic representations of one example of the features' cross-sections at different stages of a filling process. Specifically, cross-section 321 represents an example of the feature after completing one of the initial deposition operations 203. At this stage of the process, substrate 303 may have a layer 323 of tungsten-containing materials deposited over under-layer 313. The size of the cavity near the opening may be narrower that inside the feature, for example, due to overhang 315 of the under-layer 313 and/or poor step coverage of the deposited layer 323, which are described in more detail above in the context of FIG. 1.

Returning to FIG. 2, the deposition operation 203 proceeds until the deposited layer (e.g., the layer 323) reaches a certain thickness. This thickness may depend on the cavity profile and opening size. In certain embodiments, the average thickness of the deposited layer near the opening may be between about 5% and 25% of the feature cross-sectional dimension including any under-layers, if ones are present. In other embodiments (not shown), the feature may be completely closed during the deposition operation 203 and then later re-opened during the WClₓ etch operation. According to various embodiments, block 203 may take place in one or more chambers or in one or more stations of a chamber.

The process continues with changing process conditions to switch to an etching regime (block 205). Tungsten chloride compounds such as WCl₆ can etch deposited tungsten by forming various tungsten chloride WClₓ compounds such as W₂Cl₁₀, WCl₅, etc. that will react with the deposited tungsten. (It should be noted that WCl₅ occurs naturally as the dimer W₂Cl₁₀, however it is the same material). Similarly, any WClₓ or mixtures thereof used may form various tungsten chloride compounds that will react with the deposited tungsten. Block 205 involves changing one or more process conditions such as but not limited to temperature, pressure, WClₓ (e.g., WCl₅ or WCl₆) concentration, H₂ flow, and Ar (or other carrier gas flow) such that WClₓ will have a net etch, rather than deposition, of tungsten deposited in the feature. In some embodiments, the WClₓ precursor itself may be changed, e.g., from WCl₅ to WCl₆. Similarly, if a mixture such as WCl₆/WCl₅ is used, the relative amounts of the components may be changed.

According to various embodiments, block 205 may involve temporal switching or spatial switching. Temporal switching of the process parameters may be performed if the substrate remains stationary in a particular environment such as chamber or station. Spatial switching may involve moving the substrate to a different environment. Accordingly, depending on the implementation, block 205 may involve changing a pedestal temperature, a chamber pressure, gas flow rates, etc. of a chamber or station and/or moving the substrate to another chamber or station having different process parameters. According to various embodiments, block 205 may involve step changes to one or more process parameters and/or continuous modulation of one or more process parameters.

The method 200 then continues with etching deposited tungsten using WClₓ as an etchant (block 207). In some embodiments, the etching is non-conformal, such that more tungsten is etched near the opening than further in the feature. Non-conformal etching can also be referred to as preferential or low-step coverage etch. To obtain a preferential (or low step coverage) etch, the etch process conditions may be appropriately designed; a combination of the right etch temperature, etchant flow and etch pressure can help to achieve the desired conformality. An under-layer, such as a diffusion barrier layer, may be used as an etch-stop layer.

The reduction in the average thickness of the deposited layer near the opening may be greater than that inside the feature as a result of performing block 203. In certain embodiments, the reduction near the opening is at least about 10% greater than the reduction inside the feature or, in more specific embodiments, is at least about 25% greater. In some embodiments, operation 207 may be performed up to the point at which the substrate or any under-layer, if one is present, is exposed to the etchant. The tungsten layer remaining after operation 207 may be characterized with step coverage. In certain embodiments, step coverage of the etched layer is at least about 75%, more specifically at least about 100%, or at least about 125%, more even more specifically at least about 150%.

In certain embodiments, the substrate may include one or more features that are closed during the deposition operation 203 and remain closed during the etch operation 207. For example, a substrate may include small, medium size, and large features. Some small features may close during the initial deposition operation and never open again. Medium size features may close during later cycles and remain closed while other larger features are being filled. In certain embodiments, features may be present at different vertical levels of the substrates, e.g., in a dual-damascene arrangements. The features on lower-levels may close earlier than features in higher-levels.

In certain embodiments, the deposition operation 203 may only temporarily close the feature. Unlike closing the feature during a final filling operation, such as operation 211 described below, or in the situation with multiple features of different sizes and vertical positions described above, the seam during this temporary closure may be still unacceptably large or start too close to the field region. In these embodiments, the etch operation 207 may be designed in such a way that the first part of the operation 207 is used to re-open the feature and then the next part of the operation 207 is used for non-conformal etch of the deposited material. The process conditions in these two parts may be the same or different. For example, the etchant flow rate may be higher during the first part of the operation 207 and then decreased as the feature opens up.

A deposition-etch cycle including the WClₓ deposition operation 203 and the WClₓ etch operation 207 may be repeated one or more times as indicated by decision block 208. For example, it may be difficult to achieve desirable step coverage after one cycle particularly in small features with large overhangs. Considerations in a decision 208 whether to proceed with another cycle include overhang size, feature size, feature aspect ratio, feature bowing, as well as seam size and seam location requirements.

In certain embodiments, process parameters for one or both operations in the next cycle may be changed (block 209). For example, net deposition during initial cycles may be greater than in the later cycles because the deposited layer is still thin and the risk of contamination during etching is high. At the same time, the cavity is more open initially and the risk of closing is lower. For example, initial deposition cycles may be performed at slower rates (driven by lower temperatures) to achieve greater control over amounts of the tungsten containing materials deposited on the partially manufactured substrate. Slower rates may lead to a more conformal deposition, which may be needed for certain feature types. Subsequent deposition cycles may be performed at faster deposition rates (driven by higher temperatures) since control over a deposited thickness may be less critical and/or previous deposition-etching cycles may profile the cavities of the features in such way that these cavities are less likely to close prematurely. Etching may also be controlled, for example, by using different precursors, controlling temperature, adjusting the precursor concentration, and the like.

Further, block 203 may be modified from cycle-to-cycle. For example, in an initial cycle, it may involve a sequential CVD process as described above. Sequential CVD processes are generally slower than non-sequential CVD processes and so offer greater control. In a subsequent cycle, block 203 may be a non-sequential CVD process.

Returning to FIG. 3A, cross-section 331 depicts the feature after a non-conformal etch. Thus, cross-sections 321 and 331 may represent the first cycle or, more generally, one of the initial cycles. The deposited layer 323 during this cycle may be too thin to completely compensate for or offset various seam formation causes, such as the overhang 315. For example, after the selective removal operation the cavity shown in cross-section 331 is still narrower near the opening than inside the feature. In certain embodiments, this difference may be sufficiently small that the process continues to a final filling operation without repeating the deposition-etch cycle.

Cross-sections 341 and 351 illustrate the substrate 303 during and after later cycles. First, cross-section 341 shows a new deposited layer 343 formed over etched layer 333. The feature with layer 343 may have an improved profile reflecting better step coverage achieved during the previous cycles. However, the profile of the cavity may still not allow proceeding to final filling and another etching operation may be needed to further shape this cavity. Cross-section 351 represents the substrate 303 at a stage prior to a final deposition to complete the fill. The cavity is wider near the opening than inside the cavity. In certain embodiments, step coverage of the new deposited layer is at least about 10% greater than that of the initially deposited layer and may be about at least about 20% greater or at least about 30% greater.

After one or more deposition-etch cycles are performed to partially fill the feature and shape the feature profile, the process may then continue with a final filling operation 211. This operation may be in some aspects similar to the deposition operation 203. The main distinction is that the operation 211 proceeds until the feature is completely closed and it is not followed by an etching operation to open the feature. Returning to FIG. 3A, cross-section 361 represents an example of substrate 303 after the final filling operation with no seam present. In certain embodiments, the feature still has a seam, but it is smaller and has a reference point positioned further away from the field region than in a conventionally filled feature. In some implementations, the fill may proceed in a bottom-up manner. FIG. 3B shows an example of such a fill.

In some embodiments, both the deposition operation 203 and the etch operation 207 are non-plasma operations. In some embodiments, the etch operation 207 may be plasma-enhanced, with a remote or in situ plasma assisting etch species generation. Further in certain embodiments, an ion beam, e.g., an Ar ion beam may be included. For example, various chlorine species may be absorbed onto the deposited tungsten, with Ar ions then introduced to desorb the WClₓ byproduct.

In some embodiments, the deposition and etch operations 203 and 207 may overlap in part or be simultaneous. For example, the process conditions may be set in which there is net deposition at the bottom of feature and net etch at the top of the feature. According to various embodiments, block 205 may or may not be performed depending on the process. For example, process conditions may be such that a precursor and etchant species are in the chamber at the same time allowing for both deposition and etching reactions to occur simultaneously. To achieve greater net deposition inside the feature than near the opening, the process conditions may be such that the etching reaction is mass-transport limited and, therefore, depends on the etchant concentration. At the same time, the deposition reaction is not mass-transport limited and proceeds at about the same rates inside the feature and the opening. Various process conditions, including reducing agent or other reactant flow rates, introduction of plasma species, temperature, etc. may be adjusted (e.g., gradually or in stepwise fashion). Once no more cycles are desired, the process may optionally transition to a final feature operation (block 211).

In certain embodiments, a process chamber may be equipped with various sensors to perform in-situ metrology measurements to identify the extent of the deposition operation 203 and the subsequent etch operation 207. Examples of in-situ metrology include optical microscopy and X-Ray Fluorescence (XRF) for determining thickness of deposited films. Further, infrared (IR) spectroscopy may be used to detect amounts of tungsten chlorides (WClₓ) generated during etching operations. Residual gas analysis (RGA) may be used to detect gases (reactants/by products) using mass spectroscopy.

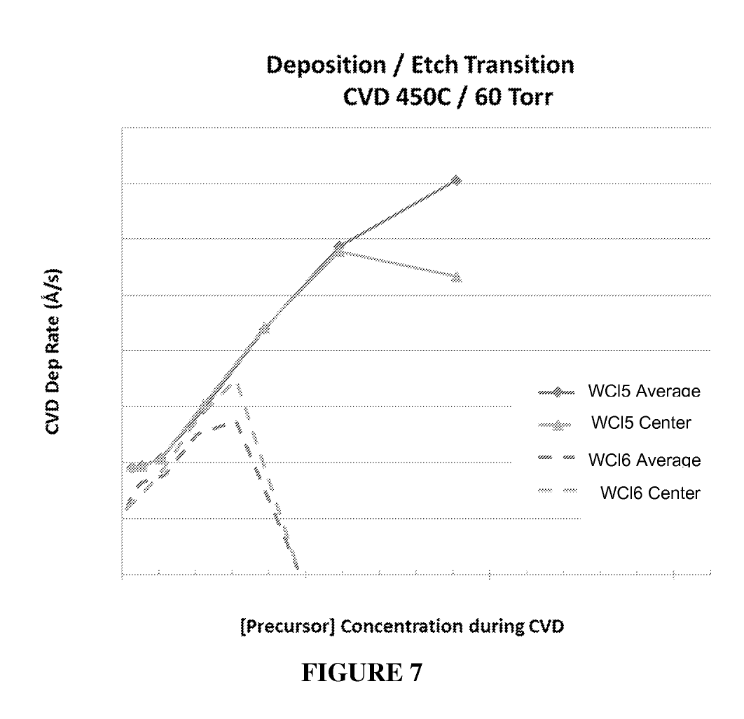

According to various embodiments, process conditions including substrate temperature, chamber pressure, and carrier flow rate may be varied to switch between deposition and etch regimes and tailor the etch. As described below with respect to FIG. 7, a tungsten chloride precursor concentration may be varied to switch between deposition and etch regimes and tailor the etch. Example substrate temperatures can range from 300° C. to 650° C., example pressures can range from 5 Torr to 760 Torr, or 5 Torr to 100 Torr, example precursor (WClₓ) temperatures can range from 110° C. to 180° C. At various process conditions, W can be either deposited, partially etched, or etched together with the barrier, down to a dielectric layer.

For example, in some embodiments, conditions that cause high WClₓ flux may be used for high etching and no deposition. In some embodiments, temperature may be increased for more stable deposition. Table 1, below, shows the results of WCl₆/H₂ CVD at various temperatures, carrier flows and pressures. (Although the WCl₆/H₂ exposure operation is referred to as CVD, at some conditions as shown below, the process is in an etch and not deposition regime). Prior to the WCl₆/H₂ CVD operation, a tungsten nucleation layer was deposited on a 100 Angstrom TiN layer using two PNL cycles of B₂H₆/WCl₆ at 450° C. Each WCl₆/H₂ CVD operation was run for 10 minutes. Tungsten thickness and TiN loss were measured, and shown in Table 1. Temperature is in ° C., Ar carrier flow in sccm, and pressure in Torr.

TABLE 1
Etching conditions of WF₆/H₂ as etchant.

| | | | Ar | | | W center |
|---|---|---|---|---|---|---|
| | Pattern | | Carrier | | TiN etched | thickness |
| Process | (Temp/Flow/Pressure) | Temperature | Flow | Pressure | (Angstroms) | (Angstroms) |
| 1 | −−− | 450 | 50 | 20 | 55.7 | 4.9 |
| 2 | −−+ | 450 | 50 | 60 | 0.5 | 440.7 |
| 3 | −+− | 450 | 300 | 20 | 128.3 | 6.6 |
| 4 | −++ | 450 | 300 | 60 | 28.6 | 24.9 |
| 5 | +−− | 550 | 50 | 20 | −1.2 | 895.1 |
| 6 | +−+ | 550 | 50 | 60 | 1.5 | 402.6 |
| 7 | ++− | 550 | 300 | 20 | 19.9 | 23.2 |
| 8 | +++ | 550 | 300 | 60 | 2.2 | 124.8 |

The nucleation film was grown in the same conditions for all of the coupons with about 50 Angstroms deposited; when etching conditions occur, it is etching the nucleation layer and the underlying TiN layer.

The results in Table 1 show that 450° C. is less stable for deposition than 550° C. At 450° C. and the low pressure of 20 Torr, there is no deposition and severe etching, regardless of the carrier flow rate. At the high pressure of 60 Torr, there is deposition only at the low carrier flow rate of 50 sccm with no deposition at the high carrier flow rate.

At 550° C. and at low pressure of 20 Torr, there is etching only at higher carrier flow however the etching is not as severe as the 450° C., 20 Torr, and high carrier flow case (compare coupon 7 to coupon 3). There is no etching at 60 Torr, regardless of carrier flow rate.

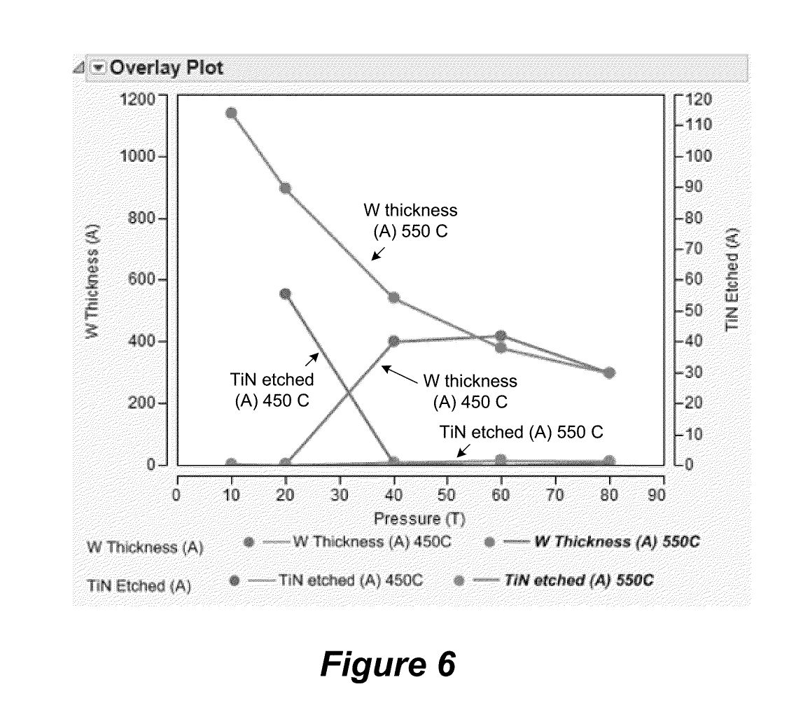

Low pressure and high carrier flow result in the highest flux and the most etching. The etch effect is more severe at 450° C. as noted above. A pressure curve was obtained, showing that the highest deposition rate is achieved at 550° C., and low pressure of 10T, using low carrier flow. See FIG. 6, which show tungsten (W) thickness and titanium nitride (TiN) etched thickness as a function of pressure for WCl₆/H₂ exposure at 450° C. and 550° C.

WClₓ flux may be increased by increasing WClₓ concentration. FIG. 7 is a graph showing CVD deposition rate as a function of precursor concentration for WCl₅ and WCl₆. An inflection indicates a switch from deposition to etching regimes. Of these precursors, WCl₅ has a lower etch rate, such that for the same concentration, WCl₆ etches more. For both precursors, increasing concentration can switch from a deposition to an etching regime. In the experimental results shown in FIG. 7, etching starts at the center of the wafer, possibly due to increased temperature at the center. However, it should be noted that this is due to the experimental nature of the processing and uniform deposition/etching across a wafer may be accomplished with appropriate temperature and gas flow controls. Precursor concentration refers to volumetric flowrate of the precursor as a percentage of total flowrate. Example concentrations range from 0.5% to 5%. In many systems, it is possible to achieve deposition or etching at most reasonable temperatures and pressures (e.g., those within the ranges given above) by varying concentration appropriately.

In some implementations, switching to an etching regime may involve lowering the temperature while switching to a deposition regime may involve raising the temperature. In some implementations, temperature may be held constant with other process parameters varied to go from deposition to etch and vice versa. In some implementations, temperature may be varied by itself alongside one or more other process parameters.

In some implementations, switching to an etching regime may involve lowering the pressure while switching to a deposition regime may involve raising the pressure. In some implementations, pressure may be held constant with other process parameters varied to go from deposition to etch and vice versa. In some implementations, pressure may be varied by itself or alongside one or more other process parameters.

In some implementations, switching to an etching regime may involve raising the carrier flow rate while switching to a deposition regime may involve lowering the carrier flow rate. In some implementations, carrier flow rate may be held constant with other process parameters varied to go from deposition to etch and vice versa. In some implementations, carrier flow rate may be varied alongside one or more other process parameters.

In some implementations, switching to an etching regime may involve increasing a WClₓ concentration while switching to a deposition regime may involve lowering a WClₓ concentration. In some implementations, WClₓ concentration may be held constant with other process parameters varied to go from deposition to etch and vice versa. In some implementations, WClₓ concentration may be varied by itself or alongside one or more other process parameters.

Apparatus

Any suitable chamber may be used to implement the disclosed embodiments. Example deposition apparatuses include various systems, e.g., ALTUS® and ALTUS® Max, available from Lam Research Corp., of Fremont, Calif., or any of a variety of other commercially available processing systems. The process can be performed on multiple deposition stations in parallel.

In some embodiments, the tungsten nucleation process is performed at a first station that is one of two, five, or even more deposition stations positioned within a single deposition chamber. In some embodiments, various steps for the nucleation process are performed at two different stations of a deposition chamber. For example, the substrate may be exposed to diborane (B₂H₆) in a first station using an individual gas supply system that creates a localized atmosphere at the substrate surface, and then the substrate may be transferred to a second station to be exposed to a FFW precursor such as tungsten hexachloride (WCl₆) or tungsten pentachloride (WCl₅) to deposit the nucleation layer. In some embodiments, the substrate may then be transferred back to the first station for a second exposure of diborane. Then the substrate may be transferred to the second station for exposure to WCl₆ (or other tungsten chloride) to complete tungsten nucleation and proceed with bulk tungsten deposition in the same or different station. One or more stations can then be used to perform chemical vapor deposition (CVD) as described above. One or more stations can then be used to perform etching as described above.

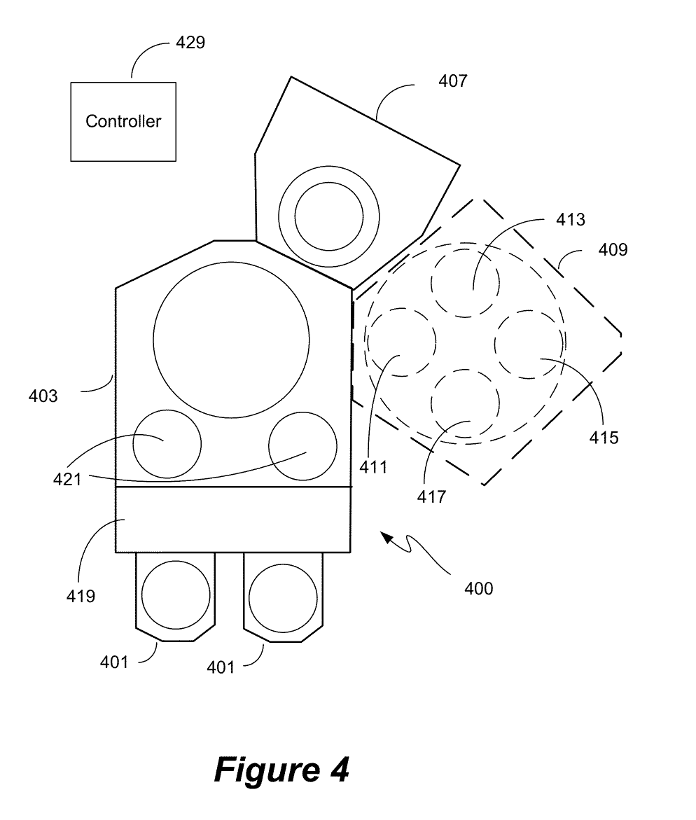

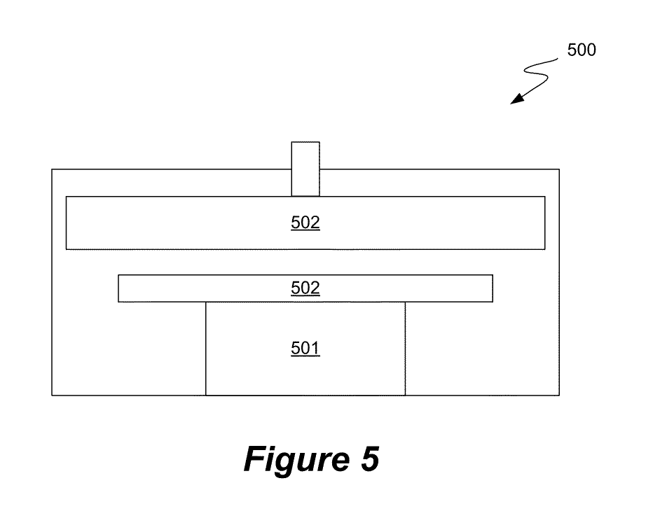

FIG. 4 is a block diagram of a processing system suitable for conducting tungsten thin film deposition and etch processes in accordance with embodiments of the invention. The system 400 includes a transfer module 403. The transfer module 403 provides a clean, pressurized environment to minimize the risk of contamination of substrates being processed as they are moved between the various reactor modules. Mounted on the transfer module 403 is a multi-station reactor 409 capable of performing PNL deposition, as well as CVD deposition and etch according to embodiments of the invention. Chamber 409 may include multiple stations 411, 413, 415, and 417 that may sequentially perform these operations. For example, chamber 409 could be configured such that stations 411 and 413 perform PNL deposition, and stations 413 and 415 perform CVD. Each deposition station includes a heated wafer pedestal and a showerhead, dispersion plate or other gas inlet. An example of a deposition station 500 is depicted in FIG. 5, including wafer support 502 and showerhead 503. A heater may be provided in pedestal portion 501.

Also mounted on the transfer module 403 may be one or more single or multi-station modules 407 capable of performing plasma or chemical (non-plasma) pre-cleans. The module may also be used for various other treatments, e.g., reducing agent soaking. The system 400 also includes one or more (in this case two) wafer source modules 401 where wafers are stored before and after processing. An atmospheric robot (not shown) in the atmospheric transfer chamber 419 first removes wafers from the source modules 401 to loadlocks 421. A wafer transfer device (generally a robot arm unit) in the transfer module 403 moves the wafers from loadlocks 421 to and among the modules mounted on the transfer module 403.

In certain embodiments, a system controller 429 is employed to control process conditions during deposition. The controller will typically include one or more memory devices and one or more processors. The processor may include a CPU or computer, analog and/or digital input/output connections, stepper motor controller boards, etc.

The controller may control all of the activities of the deposition apparatus. The system controller executes system control software including sets of instructions for controlling the timing, mixture of gases, chamber pressure, chamber temperature, wafer temperature, radio frequency (RF) power levels if used, wafer chuck or pedestal position, and other parameters of a particular process. Other computer programs stored on memory devices associated with the controller may be employed in some embodiments.

Typically there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language. Alternatively, the control logic may be hard coded in the controller. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place.

The computer program code for controlling the deposition and other processes in a process sequence can be written in any conventional computer readable programming language: for example, assembly language, C, C++, Pascal, Fortran or others. Compiled object code or script is executed by the processor to perform the tasks identified in the program.

The controller parameters relate to process conditions such as, for example, process gas composition and flow rates, temperature, pressure, plasma conditions such as RF power levels and the low frequency RF frequency, cooling gas pressure, and chamber wall temperature. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

In some implementations, a controller 429 is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 429, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 429 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 429 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 429, in some implementations, may be a part of or coupled to a computer that is integrated with, coupled to the system, otherwise networked to the system, or a combination thereof. For example, the controller 429 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 429 receives instructions in the form of data, which specify parameters for each of the processing steps to be performed during one or more operations. It should be understood that the parameters may be specific to the type of process to be performed and the type of tool that the controller 429 is configured to interface with or control. Thus as described above, the controller 429 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 429 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in pedestal or chuck. Appropriately programmed feedback and control algorithms may be used with data from these sensors to maintain desired process conditions. The foregoing describes implementation of embodiments of the invention in a single or multi-chamber semiconductor processing tool.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of depositing tungsten on a substrate, the method comprising:
exposing the substrate to a tungsten chloride (WClₓ) precursor and a reducing agent at a first set of conditions to deposit a first tungsten layer in a feature on a substrate by chemical vapor deposition (CVD); and
exposing the substrate to a WClₓ precursor and the reducing agent at a second set of conditions to etch the first tungsten layer.

2. The method of claim 1, wherein tungsten chloride is selected from WCl₂, WCl₄, WCl₅, WCl₆, and mixtures thereof.

3. The method of claim 1, wherein etching the first tungsten layer comprises a non-conformal etch such that the reduction in the average thickness of the first tungsten layer near an opening of the feature is greater than the reduction in the average thickness of first tungsten layer inside the feature.

4. The method of claim 1, wherein the reducing agent is hydrogen.

5. The method of claim 1, wherein transitioning from the first set of conditions to the second set of conditions comprises lowering a temperature.

6. The method of claim 1, wherein transitioning from the first set of conditions to the second set of conditions comprises increasing a WClₓ flux.

7. The method of claim 1, wherein the WClₓ in the deposition operation is the same as the WClₓ precursor in the etching operation.

8. The method of claim 1, wherein transitioning from the first set of conditions to the second set of conditions comprises changing the WClₓ precursor.

9. The method of claim 1, wherein transitioning from the first set of conditions to the second set of conditions comprises increasing a WClₓ concentration.

10. A method of filling a feature with tungsten comprising:
exposing a feature partially filled with tungsten to WClₓ to thereby remove a portion of the tungsten in the partially filled feature.

11. The method of claim 10, wherein the reduction in the average thickness of the tungsten near an opening of the feature is greater than the reduction in the average thickness of tungsten inside the feature.

12. The method of claim 10, further comprising exposing the partially filled feature to hydrogen.

13. An apparatus for processing substrates, the apparatus comprising:
(a) one or more process chambers comprising a pedestal configured to hold a substrate;
(b) at least one outlet for coupling to a vacuum;
(c) one or more process gas inlets coupled to one or more process gas sources; and
(d) a controller for controlling operations in the apparatus, comprising machine-readable instructions for:
(i) introducing a tungsten chloride and a reducing agent to one of the one or more process chambers; and
(ii) after (i) introducing a tungsten chloride and a reducing agent to one of the one or more process chambers, wherein transitioning from (i) and (ii) comprises instructions for switching from an deposition regime to an etching regime.

14. The apparatus of claim 13, wherein the controller comprises instructions for transitioning from (i) to (ii) by increasing a tungsten chloride concentration.

15. The apparatus of claim 13, wherein the controller comprises instructions for transitioning from (i) to (ii) by decreasing a temperature of the substrate.

16. The apparatus of claim 13, wherein the controller comprises instructions for transitioning from (i) to (ii) by changing a tungsten chloride precursor.

17. The apparatus of claim 13, wherein the controller comprises instructions for transitioning from (i) to (ii) by increasing a tungsten chloride flowrate.
